(19) United States
(12) Patent Application Publication
(10) Pub. No.: US 2012/0061797 A1
(43) Pub. Date: Mar. 15, 2012

(54) SEMICONDUCTOR DEVICE AND METHOD OF FABRICATING THE SAME

(75) Inventor: Masahiko Kanda, Kanagawa-ken (JP)

(73) Assignee: KABUSHIKI KAISHA TOSHIBA, Tokyo (JP)

(21) Appl. No.: 13/041,601

(22) Filed: Mar. 7, 2011

(30) Foreign Application Priority Data
Sep. 14, 2010 (JP) 2010-205995

(51) Int. Cl. H01L 23/525; H01L 21/768; H01L 21/28

(52) U.S. Cl. 257/530; 438/586; 257/E23.147; 257/E21.199; 257/E21.592

(57) ABSTRACT

According to one embodiment, a semiconductor device including a substrate, and an anti-fuse element including a first insulator formed on the substrate, a conductive film formed on the first insulator, the conductive film including a silicide film, a contact formed on the substrate, the contact being disposed adjacent to the conductive film with a second insulator interposed between the contact and the conductive film, the contact being short-circuited to the silicide film.

### CROSS REFERENCE TO RELATED APPLICATION

This application is based upon and claims the benefit of priority from prior Japanese Patent Application No. 2010-205995, filed on Sep. 14, 2010, the entire contents of which are incorporated herein by reference.

### FIELD

Exemplary embodiments described herein generally relate to a semiconductor device including an anti-fuse element and a method of fabricating the semiconductor device including the anti-fuse element.

### BACKGROUND

An anti-fuse element is an element that is normally insulating but becomes conducting when a voltage is applied to the anti-fuse element. An oxide breakdown fuse of the MOSFET (Metal-Oxide-Semiconductor Field-Effect Transistor) type, using the anti-fuse element as a memory has been proposed.

The oxide breakdown fuse of the MOSFET type is an anti-fuse element in which “1” data are written when there is breakdown of a gate insulator (oxide film) and “0” data are written when there is no breakdown of the gate insulator, where the gate insulator is caused to break down by a current stress.

Such anti-fuse elements are used as redundancies of large-capacity memories, such as DRAMs (Dynamic Random Access Memories) and SRAMs (Static Random Access Memories), for example, or as chip IDs to store information for management.

The oxide breakdown fuse of the MOSFET type has a structure similar to that of a normal MOSFET. Specifically, a channel region is formed between source and drain diffusion layers in a semiconductor substrate, and a gate insulator and a gate electrode are formed on the channel region.

In addition, a contact is formed on each of the source and drain regions.

Since the oxide breakdown fuse of the MOSFET type has the structure similar to that of the normal MOSFET as described above, there is a need for specifying the gate width, the contact diameter or the like, and therefore there is a limitation in reduction of the area (miniaturization).

### BRIEF DESCRIPTION OF THE DRAWINGS

FIG. 1 is a plan view showing a structure of an anti-fuse element according to a first embodiment.

FIG. 2 is a cross-sectional view showing a structure of the anti-fuse element according to the first embodiment before writing.

FIG. 3 is a cross-sectional view showing a structure of the anti-fuse element according to the first embodiment after writing.

FIG. 4 is a cross-sectional view showing a process of fabricating the anti-fuse element according to the first embodiment.

FIG. 5 is a cross-sectional view showing a process of fabricating the anti-fuse element according to the first embodiment, following FIG. 4.

FIG. 6 is a cross-sectional view showing a comparative example of an anti-fuse element related to the first embodiment.

FIG. 7 is a cross-sectional view showing a structure of an anti-fuse element according to a second embodiment before writing.

FIG. 8 is a cross-sectional view showing a structure of the anti-fuse element according to the second embodiment after writing.

FIG. 9 is a cross-sectional view showing a structure of a modification of the anti-fuse element according to the second embodiment after writing.

FIG. 10 is a block diagram schematically showing an application example of the anti-fuse element according to each embodiment.

FIG. 11 is a circuit diagram schematically showing the application example of the anti-fuse element according to each embodiment.

### DETAILED DESCRIPTION

According to one embodiment, a semiconductor device including a substrate, and an anti-fuse element including a first insulator formed on the substrate, a conductive film formed on the first insulator, the conductive film including a silicide film, a contact formed on the substrate, the contact being disposed adjacent to the conductive film with a second insulator interposed between the contact and the conductive film, the contact being short-circuited to the silicide film.

Embodiments will be described below in detail with reference to the attached drawings mentioned above. Throughout the attached drawings, similar or same reference numerals show similar, equivalent or same components.

### First Embodiment

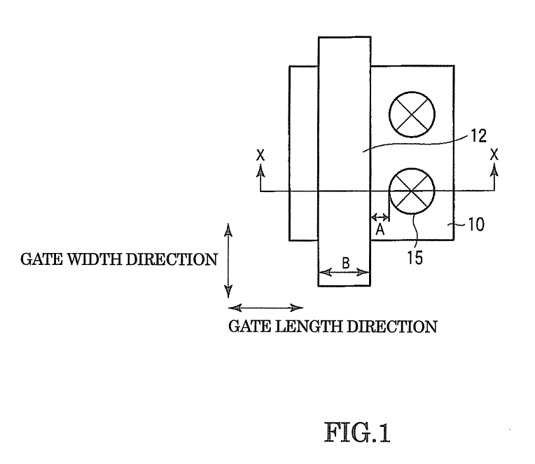

An anti-fuse element of a semiconductor device according to a first embodiment will be described with reference to FIG. 1 to FIG. 6. The first embodiment is an example of an anti-fuse element in which “1” data or “0” data are stored by breakdown of an oxide film between agate electrode and a contact.

Note that, since the embodiment can be implemented by using the MOSFET fabrication technology, the terms used for MOSFETs, such as a gate electrode, a gate insulator, a gate length, a gate width, or the like, are used in the following description. The embodiment, however, can bring about the same advantageous effects and be implemented, even without MOSFET structure, as will be described later.

### [Structure]

Hereinafter, the structure of the anti-fuse element according to the first embodiment will be described with reference to FIG. 1 to FIG. 3.

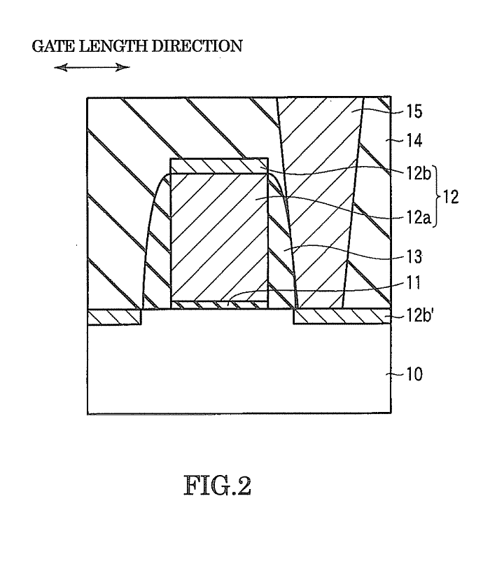

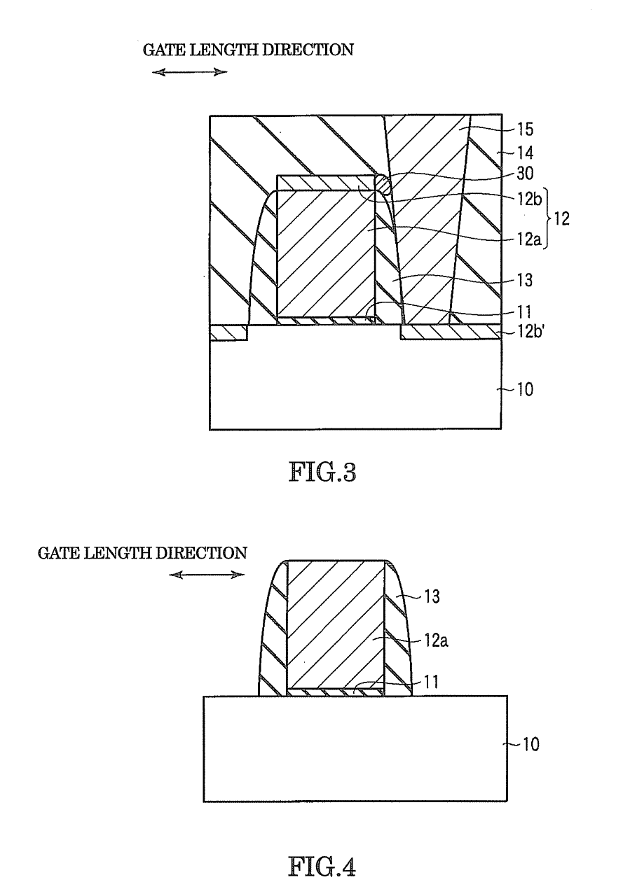

FIG. 1 is a plan view showing the anti-fuse element according to the first embodiment. FIG. 2 is a cross-sectional view showing the anti-fuse element according to the first embodiment before writing taken in the gate length direction, and is a cross-sectional view taken along the line X-X in FIG. 1. FIG. 3 is a cross-sectional view showing the anti-fuse element according to the first embodiment after writing taken in the gate length direction, and is a cross-sectional view taken along the line X-X in FIG. 1.

As shown in FIG. 2, the anti-fuse element according to the first embodiment includes a substrate 10, a gate insulator (first insulator) 11, a gate electrode (conductive film) 12, a sidewall insulator 13, an inter-layer insulator (second insulator) 14, and a contact 15.

The substrate 10 is a silicon substrate, for example. The gate electrode 12 is formed on the substrate 10 with the gate insulator 11 interposed between the gate electrode 12 and the substrate 10. The gate insulator 11 is formed of a silicon oxide film or a silicon nitride film, for example.

The gate electrode 12 includes a poly-crystalline silicon film 12a formed on the gate insulator 11 and a silicide film 12b formed on the poly-crystalline silicon film 12a. In other words, the gate electrode 12 includes the poly-crystalline silicon film 12a on the lower portion side and includes the silicide film 12b on the upper portion side. The silicide film 12b is formed of a compound of Ni and Si or a compound of Pt and Si. Moreover, a silicide film 12b′ similar to the silicide film 12b is formed on the surface of the substrate 10. The silicide films 12b and 12b′ have an excellent conductivity, so that writing operation, which will be described later, can be performed with a low current. Note that the gate electrode 12 may be a metal gate electrode formed of only the silicide film 12b or may include at least partially the silicide film 12b.

The sidewall insulator 13 is formed on the side surface of the gate insulator 11 and on the side surface of the gate electrode 12. The sidewall insulator 13 is formed of a silicon nitride film, for example. Here, the sidewall insulator 13 is not formed on at least a portion of the side surface of the silicide film 12b in the gate electrode 12. Note that the sidewall insulator 13 does not necessarily have to be formed.

The contact 15 is formed on the substrate 10, and is electrically connected to the substrate 10. In addition, the contact 15 is disposed adjacent to at least one side of the gate insulator 11 and the gate electrode 12 via the side insulator 13 or the inter-layer insulator 14. The contact 15 is formed of W, for example. Note that, although there is no limitation on the shape of the contact 15, forming the contact 15 as a tapered shape with a diameter increasing from the lower portion side toward the upper portion side makes it possible to promote the advantageous effects of the embodiment. Specifically, the tapered shape makes the distance between the silicide film 12b formed on the upper portion side of the gate electrode 12 and the contact 15 shorter than the distance between the poly-crystalline silicon film 12a formed on the lower portion side of the gate electrode 12 and the contact 15, and thus makes it possible to establish conduction between the silicide film 12b and the contact 15 with a low current.

Moreover, the contact 15 may be or may not be in contact with the sidewall insulator 13. Furthermore, a barrier metal (not illustrated) is formed at the interfaces of the contact 15, the substrate 10, and the inter-layer insulator 14, which will be described later. The barrier metal is formed of Ti, TiN, or Ta, for example.

The inter-layer insulator 14 is formed on the entire surface. More specifically, the inter-layer insulator 14 is formed on the substrate 10, on and around the gate electrode 12, as well as around the contact 15. To put it differently, the inter-layer insulator 14 is formed between the contact 15 and at least a portion of the silicide film 12b in the gate electrode 12. The inter-layer insulator 14 is formed of a silicon oxide film, for example.

As shown in FIG. 1, the contact 15 in the embodiment is formed in such a manner as to be spaced apart from the gate electrode 12 by a predetermined distance A (nm) in the gate length direction. In addition, multiple contacts 15 may be formed and arranged in the gate width direction, as illustrated.

The distance A is determined according to the precision in the fabricating processes, and is such a distance that the gate electrode 12 and the contact 15 are short-circuited to each other when a programming voltage, which will be described later, is applied to the gate electrode 12 (or the contact 15). More specifically, the distance A is obtained by the following formula (1) using the value of variation in size of the gate electrode X (nm), the value of variation in size of the contact Y (nm), and a stepper alignment Z (nm).

$$\begin{matrix}[ Formula 1 ] & \\ A \leq \sqrt{{( \frac{X}{2} )}^{2} + {( \frac{Y}{2} )}^{2} + {( \frac{Z}{2} )}^{2}} & ( 1 )\end{matrix}$$

The distance A and the gate length B can be laid out according to the minimum rule. More specifically, in the case of the generation of a cell size of 40 nm, the distance A is 15 nm, for example, and the gate length B is 40 nm, for example.

In the writing operation, a programming voltage VBP of approximately 1.8 V, for example, is applied to the gate electrode 12 (or the contact 15). In addition, the contact (or the gate electrode 12) is set at ground potential. Accordingly, a potential difference is generated between the contact 15 and the gate electrode 12, and the current stress causes the contact 15 (the barrier metal (not illustrated) in the contact 15) and the gate electrode 12 to be short-circuited to each other. In other words, as shown in FIG. 3, a current path 30 is generated between the contact 15 and the gate electrode 12, causing the contact 15 and the gate electrode 12 to conduct to each other.

Here, the silicide film 12b has a conductivity higher than that of the poly-crystalline silicon film 12a in the gate electrode 12. In addition, a silicon nitride film (the sidewall insulator 13), which has a high break-down voltage, is not formed between the silicide film 12b and the contact 15, but a silicon oxide film (the inter-layer insulator 14), which has a low break-down voltage, is formed between the silicide film 12b and the contact 15. For these reasons, a larger current stress causes the silicide film 12b and the contact 15 to be short-circuited to each other, so that the current path 30 is generated between the silicide film 12b and the contact 15. The current path 30 is formed by the silicide film 12b spread by the current stress. In this way, the silicon oxide film (the inter-layer insulator 14) between the silicide film 12b and the contact 15 is caused to break down, so that the data “1” are written.

### [Fabrication Method]

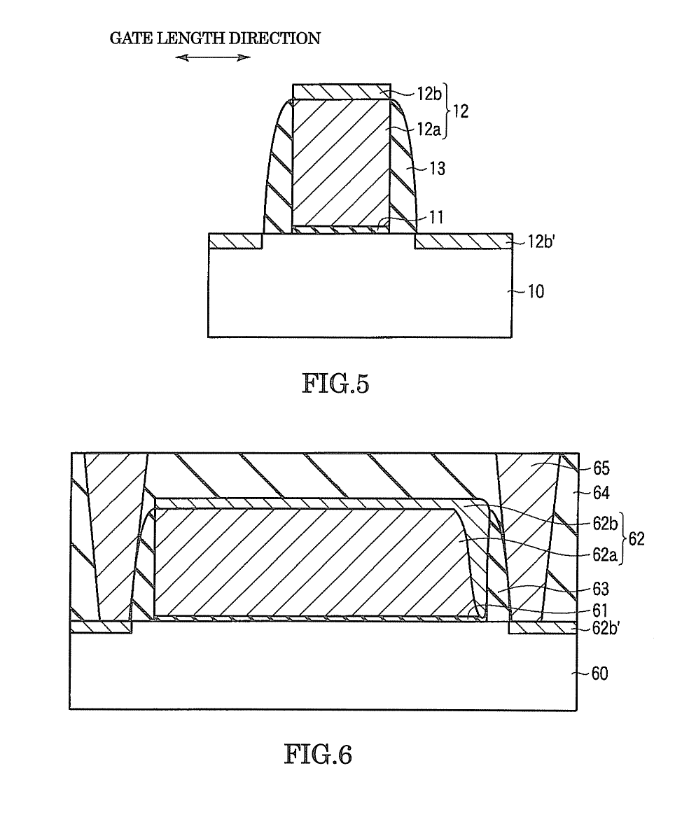

Hereinafter, an example of a method of fabricating the anti-fuse element according to the first embodiment will be described with reference to FIG. 4 and FIG. 5.

FIG. 4 and FIG. 5 show cross-sectional views of processes of fabricating the anti-fuse element according to the first embodiment.

First, as shown in FIG. 4, a gate insulator 11, which is formed of a silicon oxide film, for example, is formed on a substrate 10. As the method of forming the gate insulator 11, a CVD (Chemical Vapor Deposition) method, an ALD (Atomic Layer Deposition) method, a thermal oxidation method, or the like, for example may be employed.

Next, a poly-crystalline silicon film 12a is formed on the gate insulator 11. As the method of forming the poly-crystalline silicon film 12a, the CVD method, the ALD method, or the like, for example may be employed.

Next, the gate insulator 11 and the poly-crystalline silicon film 12a are patterned by a lithography method and a dry etching method, for example.

Next, a silicon nitride film is formed on the entire surface. Thereafter, anisotropic etching, such as RIE (Reactive Ion Etching), for example, is performed on the silicon nitride film. As a result, a sidewall insulator 13, which is formed of the silicon nitride film, is formed on the side surface of the gate insulator 11 and the poly-crystalline silicon film 12a. Note that the sidewall insulator 13 does not necessarily have to be formed.

Next, as shown in FIG. 5, a silicide film 12b is formed on the poly-crystalline silicon film 12a by a salicide process. More specifically, a metal film formed of Ni or Pt, for example, is first formed on the poly-crystalline silicon film 12a. After that, thermal processing is performed to cause the metal film and the poly-crystalline silicon film 12a to react with each other. The silicide film 12b is thus formed on the surface of the poly-crystalline silicon film 12a. Asa result, a gate electrode 12 is formed, including the poly-crystalline silicon film 12a on the lower portion side and the silicide film 12b on the upper portion side. At the same time, a silicide film 12b′ is formed on the substrate 10 as well.

At this time, the sidewall insulator 13 is not formed on at least a portion of the side surface of the silicide film 12b. In other words, at least a portion of the side surface of the silicide film 12b is exposed before deposition of an inter-layer insulator 14, which will be described later.

Next, as shown in FIG. 1, the inter-layer insulator 14, which is formed of a silicon oxide film, for example, is formed on the entire surface. As the method of forming the inter-layer insulator 14, the CVD method, the ALD method, or the like, for example may be employed.

Next, a contact hole that reaches the substrate 10 is formed in the inter-layer insulator 14. The contact hole is provided adjacent to at least one side of the gate insulator 11 and the gate electrode 12 via the sidewall insulator 13 or the inter-layer insulator 14, and is formed in such a manner as to be spaced apart from the gate electrode 12 by a predetermined distance. In addition, although the contact hole is formed desirably in a tapered shape with a diameter increasing from the lower portion side toward the upper portion side, there is no limitation on the shape of the contact hole.

An barrier metal (not illustrated) is formed on the surface of the contact hole. After that, a metal material such as W, for example, is embedded in the contact hole, thus forming a contact 15 electrically connected to the substrate 10.

As described so far, the anti-fuse element according to the first embodiment can be fabricated by the usual MOSFET fabrication technology.

### [Advantageous Effects]

According to the first embodiment described above, the anti-fuse element stores data by breakdown of the oxide film (the inter-layer insulator 14) between the gate electrode 12 and the contact 15. To put it differently, the anti-fuse element according to the embodiment does not require any normal MOSFET structures. Needless to say, the advantageous effects of the embodiment can be obtained even with the MOSFET structure. For this reason, the size of the gate electrode 12 (the gate length), the size of the contact 15 (the contact diameter), and the distance between the gate electrode 12 and the contact 15 can be laid out according to the minimum rule. This makes it possible to achieve reduction in area and thus miniaturization.

On the other hand, as shown in FIG. 6 as a comparative example, a normal oxide breakdown fuse of the MOSFET type includes a substrate 60, a gate insulator 61, a gate electrode 62 (a poly-crystalline silicon film 62a and a silicide film 62b), a sidewall insulator 63, an inter-layer insulator 64, and a contact 65.

The oxide breakdown fuse of the MOSFET type is an element in which “1” data are written when there is the breakdown of the gate insulator 61 and “0” data are written when there is no breakdown of the gate insulator 61, where the gate insulator (a silicon oxide film, for example) is caused to break down by application of a programming voltage. In other words, a current stress causes the breakdown of the gate insulator 61 to inject electrons into the substrate 60 through the gate insulator 61, so that the current path is formed, in the oxide breakdown fuse of the MOSFET type.

However, the current stress increases the temperature around the current path, in turn causing large EM (Electro Migration) of the silicide film 62b. As a result, the silicide film 62b on the broken-down portion of the gate insulator 61 expands over the entire region. Specifically, as shown in FIG. 6, the silicide film 62b on the broken-down portion of the gate insulator 61 expands over the entire region, and at the same time, a current stress is generated in the vertical direction (the stacking direction), thus spreading the silicide film 62b along the vertical direction of the gate electrode 62. Moreover, the silicide film 62b′ formed on the substrate 60 is also spread. This brings about a problem of a failed bit in which data “1” are reversed to data “0” in the reflow and the high temperature stress test.

Against the above-described problem, in the first embodiment, the breakdown of the oxide film between the gate electrode 12 and the contact 15 is caused to form the current path 30. That is to say, no current stress is generated in the vertical direction in the first embodiment, unlike the oxide breakdown fuse of the MOSFET type. For this reason, the spreading of the silicide film 62b in the vertical direction as shown in FIG. 6 is suppressed, so that the problem of a failed bit in which data are reversed can be avoided.

### Second Embodiment

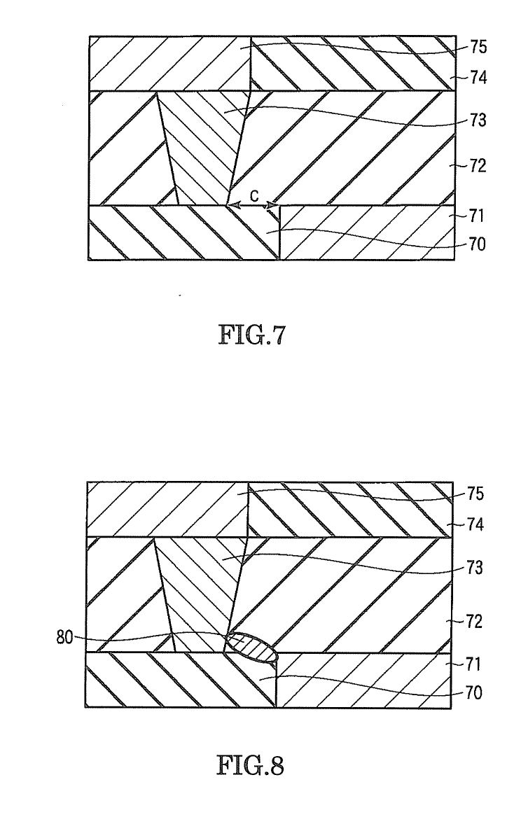

An anti-fuse element of a semiconductor device according to a second embodiment will be described with reference to FIG. 7 to FIG. 9. The second embodiment is an example of an anti-fuse element in which “1” data or “0” data are stored by breakdown of an oxide film between a wire and a via in a multilayer wiring structure.

### [Structure]

Hereinafter, the structure of the anti-fuse element according to the second embodiment will be described with reference to FIG. 7 to FIG. 9.

FIG. 7 is a cross-sectional view showing the anti-fuse element according to the second embodiment before writing. FIG. 8 is a cross-sectional view showing the anti-fuse element according to the second embodiment after writing.

As shown in FIG. 7, the anti-fuse element according to the second embodiment (not illustrated) is formed of multilayer wiring formed on a substrate. More specifically, the anti-fuse element according to the second embodiment includes a first wiring layer insulator 70, a first wire 71, a via layer insulator 72, a via 73, a second wiring layer insulator 74, and a second wire 75.

The first wiring layer insulator 70 is formed above a substrate (not illustrated), which is a silicon substrate, for example. The first wiring layer insulator 70 is formed of a silicon oxide film, for example.

The first wire 71 is formed in the first wiring layer insulator 70. The first wire 71 is formed of Cu, for example. In addition, a barrier metal (not illustrated) is formed at the interface of the first wire 71 and the first wiring layer insulator 70. The barrier metal is formed of Ti, TiN, or Ta, for example.

The via layer insulator 72 is formed on the first wiring layer insulator 70 and the first wire 71. The via layer insulator 72 is formed of a silicon oxide film, for example.

The via 73 is formed in the via layer insulator 72 and on the first wiring layer insulator 70. The via 73 is formed of Cu, for example. The via 73 is electrically connected to the second wire 75, which will be described later. In addition, although the via 73 has a tapered shape with a diameter increasing from the lower portion side toward the upper portion side, there is no limitation on the shape of the via 73. Moreover, a barrier metal (not illustrated) is formed at the interfaces of the via 73, the first wiring layer insulator 70, and the via layer insulator 72. The barrier metal is formed of Ti, TiN, or Ta, for example.

The second wiring layer insulator 74 is formed on the via layer insulator 72. The second wiring layer insulator 74 is formed of a silicon oxide film, for example.

The second wire 75 is formed in the second wiring layer insulator 74 and on the via layer insulator 72 and the via 73. The second wire 75 is formed of Cu, for example. In addition, a barrier metal (not illustrated) is formed at the interfaces of the second wire 75, the via layer insulator 72, the via 73, and the second wiring layer insulator 74. The barrier metal is formed of Ti, TiN, or Ta, for example.

The via 73 according to the embodiment is located between the first wire 71 and the second wire 75, is directly connected to the second wire 75, and is formed in such a manner as to be spaced apart from the first wire 71 by a predetermined distance C (nm). In addition, a silicon oxide film (the first wiring layer insulator 70 and the via layer insulator 72) is formed between the via 73 and the first wire 71.

The distance C is determined according to the precision in the fabricating process, and is such a distance that the via 73 and the first wire 71 are short-circuited to each other when a programming voltage, which will be described later, is applied to the first wire 71 or the second wire 75. More specifically, the distance C is obtained by the following formula (2) using the value of variation in size of the via S (nm), the value of variation in size of the wire T (nm), and a stepper alignment U (nm).

$$\begin{matrix}[ Formula 1 ] & \\ C \leq \sqrt{{( \frac{S}{2} )}^{2} + {( \frac{T}{2} )}^{2} + {( \frac{U}{2} )}^{2}} & ( 2 )\end{matrix}$$

The distance C can be laid out according to the minimum rule. More specifically, the distance C is 20 nm, for example.

In the writing operation, a programming voltage VBP of approximately 1.8 V, for example, is applied to one of the first wire 71 and the second wire 75. In addition, the other one of the first wire 71 and the second wire 75 is set at ground potential, for example. In this way, a potential difference is generated between the via 73 and the first wire 71, and the current stress causes the via 73 and the first wire 71 to be short-circuited to each other. In other words, as shown in FIG. 8, a current path 80 is generated between the via 73 and the first wire 71, causing the via 73 and the first wire 71 to conduct to each other. The current path 80 is a conductive material (Cu, for example) spread by the current stress. In this way, the silicon oxide film (the first wiring layer insulator 70 and the via layer insulator 72) between the via 73 and the first wire 71 is caused to break down, so that the data “1” are written.

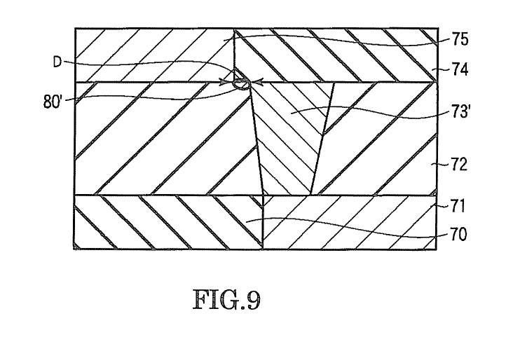

FIG. 9 shows a cross-sectional view of a modification of the anti-fuse element according to the second embodiment after writing.

In the second embodiment described above, the via 73 and the first wire 71 located in a lower layer than the via 73 are short-circuited. In other words, the current path 80 is generated between the lower end portion of the via 73 and the upper end portion of the first wire 71, which are thereby caused to conduct to each other. On the other hand, the modification is an example in which a via 73 and a second wire 75 located in an upper layer than the via 73′ are short-circuited.

As shown in FIG. 9, the via 73′ is located between a first wire 71 and the second wire 75, is directly connected to the first wire 71, and is formed in such a manner as to be spaced apart from the second wire 75 by a predetermined distance D (nm). In addition, a silicon oxide film (a via layer insulator 72 and a second wiring layer insulator 74) is formed between the via 73′ and the second wire 75.

In the writing operation, a programming voltage VBP of approximately 1.8 V, for example, is applied to one of the first wire 71 and the second wire 75. In addition, the other one of the first wire 71 and the second wire 75 is set at ground potential, for example. In this way, a potential difference is generated between the via 73′ and the second wire 75, and the current stress causes the via 73′ and the second wire 75 to be short-circuited to each other. In other words, as shown in FIG. 9, a current path 80′ is generated between the via 73′ and the second wire 75, causing the via 73′ and the second wire 75 to conduct to each other.

Here, the via 73′ has a tapered shape with a diameter increasing from the lower portion side toward the upper portion side. That is to say, since the diameter of the via 73′ is larger on the upper portion side, the distance D (nm) between the via 73′ and the second wire 75 is shorter than the distance C. Accordingly, writing with a lower current is made possible.

The anti-fuse element according to the second embodiment as described above can be fabricated by a normal fabrication technology for multilayer wiring structures. More specifically, each wire and the via may be formed by a single-damascene process or may be formed by a dual-damascene process. Each of these processes is publicly known and thus is not described herein in detail.

### [Advantageous Effects]

According to the above-described second embodiment, the same advantageous effects can be achieved.

In addition, the anti-fuse element according to the second embodiment is formed of an oxide film used for the metal wires and the via as well as between the wires. For this reason, there is no silicide, which is spread by a current stress. Therefore, it is possible to avoid the problem of a failed bit in which data are reversed.

Note that, although the anti-fuse element according to the second embodiment can achieve the advantageous effect of the embodiment in any layer of the multilayer wiring, the forming of the anti-fuse element according to the second embodiment in a lower layer portion (the first layer or the second layer, for example) makes it possible to achieve a smaller layout and thus further achieve miniaturization.

### Application Example

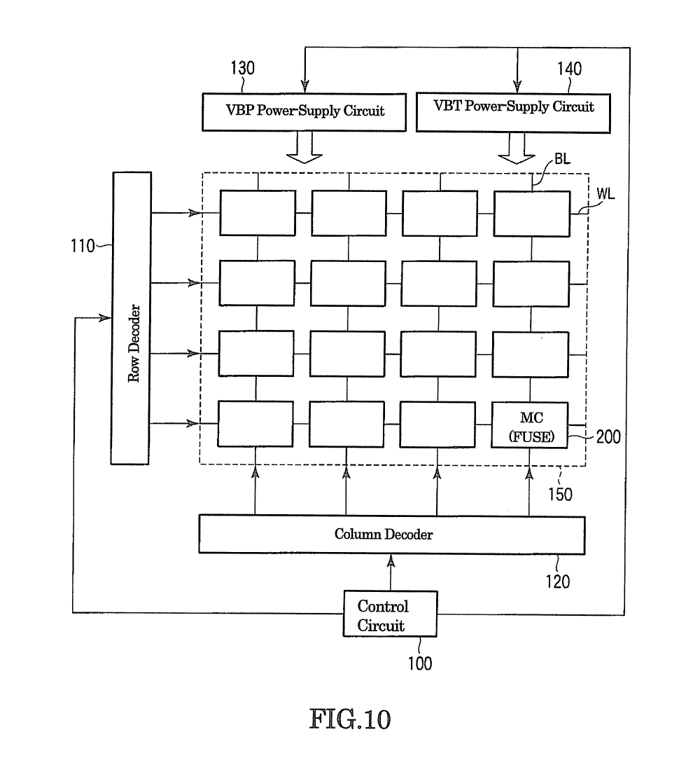

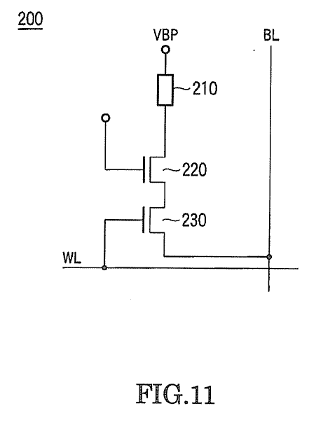

An application example of the anti-fuse element according to each of the above-described embodiments will be described with reference to FIGS. 10 and 11.

FIG. 10 shows a block diagram of a semiconductor device using the anti-fuse element according to each embodiment as a memory.

As shown in FIG. 10, the semiconductor device includes a control circuit 100, a row decoder 110, a column decoder 120, a program (VBP) power-supply circuit 130, a VBT power-supply circuit 140, an a memory cell array 150.

The control circuit 100 is configured to control the VBP power-supply circuit 130 and the VBT power-supply circuit 140 on the basis of voltages to be supplied to a memory cell 200 in writing and reading, and also to control the row decoder 110 and the column decoder 120 on the basis of an address supplied from the outside.

The row decoder 110 is configured to select a word line in accordance with the control of the control circuit 100.

The column decoder 120 is configured to select a bit line in accordance with the control of the control circuit 100. Note that the column decoder 120 includes an unillustrated sense amplifier.

The VBP power-supply circuit 130 is configured to generate a high voltage for programming and to supply the high voltage to the memory cell 200, in accordance with the control of the control circuit 100.

The VBT power-supply circuit 140 is configured to generate a voltage for barrier element, which will be described later, and to supply the voltage to the memory cell 200, in accordance with the control of the control circuit 100.

The memory cell array 150 includes multiple word lines WL and multiple bit lines BL extending orthogonal to each word line WL. Multiple memory cells 200 are disposed on the respective intersections of these multiple word lines WL and multiple bit lines BL. Each memory cell 200 includes an anti-fuse element formed therein as a memory element.

FIG. 11 shows an example of a circuit diagram of the memory cell 200 shown in FIG. 10.

As shown in FIG. 11, the memory cell 200 of the example includes an anti-fuse element 210 as a memory cell, a barrier element 220, and a selection element 230.

The anti-fuse element 210 is that in which “1” data and “0” data are written by breakdown of an oxide film caused by application of the high voltage supplied from the VEP power-supply circuit 130.

The barrier element 220 and the selection element 230 are connected in series between the anti-fuse element 210 and the bit line BL. More specifically, the anti-fuse element 210 is connected to one end of the barrier element 220, and one end of the selection element 230 is connected to the other end of the barrier element 220. Moreover, the bit line BL is connected to the other end of the selection element 230. Here, each of the barrier element 220 and the selection element 230 is formed of a MOS transistor.

The barrier element 220 has a function of preventing the high voltage supplied from the VBP power-supply circuit 130 from being applied to the selection element 230 with the barrier voltage supplied from the VBT power-supply circuit 140 being applied to the gate of the barrier element 220.

The word line WL is connected to the gate of the selection element 230, and the selection element 230 is turned on when the word line WL is selected. The selection of the word line WL is executed by the row decoder 110 in accordance with input of an address signal from the outside.

The writing operation is performed by the following procedures, for example.

First, the VBP power-supply circuit 130 is set to a voltage high enough to cause the breakdown of the oxide film of the anti-fuse element 210. In this process, the VBT power-supply circuit 140 is set to a high voltage and the word line WL and the bit line BL are set to a somewhat high potential at the same time, in order to prevent an unnecessary high voltage stress from being applied to the anti-fuse element 210, the barrier element 220, and the selection element 230.

Next, the word line WL connected to the memory cell 200 on which the writing is to be performed is selected and set to a high potential, and the other word lines WL connected to the memory cells 200 on which no writing is to be performed are set to a low potential as not being selected. Moreover, the bit line BL connected to the memory cell 200 on which the writing is to be performed is set to a low potential, and the other bit lines BL are set to a high potential. In this way, the memory cell 200 to which the word line WL with the high potential and the bit line BL with the low potential are connected is selected, and the writing is performed on the selected memory cell 200.

The high voltage supplied from the VBP power-supply circuit 130 is applied to the anti-fuse element 210 of the selected memory cell 200. Keeping this state causes the breakdown of the oxide film of the anti-fuse element 210 of the selected memory cell 200. The breakdown occurs locally in the oxide film, and a current path (the current path 30 shown in FIG. 3, the current path 80 shown in FIG. 8, or the current path 80′ shown in FIG. 9) is formed at the breakdown portion. After that, the application of the voltage supplied from the VBP power-supply circuit 130 is cut off, so that the writing operation ends.

On the other hand, the reading operation is performed by the following procedures.

First, the VBP power-supply circuit 130 is set to a voltage not to cause the breakdown of the oxide film of the anti-fuse element 210 in a state where all the word lines WL are maintained at 0 V. Moreover, the VET power-supply circuit 140 is set to a high voltage so that the barrier element 220 is made conductive. The potential of the bit line BL is initialized in the state. The potential is desirably a relatively low potential so that a sufficient voltage should be applied to the anti-fuse element 210.

Next, the word line WL is selectively set to a high potential with the bit line BL being set in a high impedance state. When the data stored in the anti-fuse element 210 is “1”, the anti-fuse element 210 is low in resistance. Accordingly, keeping the state causes the potential of the bit line BL to become a higher potential than the initial potential. On the other hand, when the data stored in the anti-fuse element 210 is “0”, the anti-fuse element 210 is high in resistance. Accordingly, the potential of the bit line BL remains the initial potential. The potential difference between the potential described above and a reference potential is detected to thus determine whether the data stored in the memory cell 200 are “0” or “1”.

Note that the circuit configuration of the memory cell 200 shown in FIG. 11 is one example, and the anti-fuse element according to the embodiment can be applied to any other various known forms.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
an anti-fuse element comprising,
a first insulator formed on a substrate,
a conductive film formed on the first insulator, the conductive film including a silicide film,
a contact formed on the substrate, the contact being disposed adjacent to the conductive film with a second insulator interposed between the contact and the conductive film, the contact being short-circuited to the silicide film.

2. The semiconductor device of claim 1, wherein
the contact has a tapered shape with a diameter increasing from a lower portion side toward a upper portion side of the contact.

3. The semiconductor device of claim 1, wherein
the silicide film is formed on an upper portion side of the conductive film.

4. The semiconductor device of claim 1, wherein
the silicide film is formed of at least one of a nickel silicide film or a platinum silicide film.

5. The semiconductor device of claim 1, wherein
the conducive film is formed of a silicide film.

6. The semiconductor device of claim 1, wherein
the second insulator is formed of a silicon oxide film.

7. The semiconductor device of claim 3, wherein
the second insulator is formed of a silicon nitride film, and
the silicon nitride film is in contact with the conductive film in a portion other than a portion where the silicide film is in contact with the contact.

8. The semiconductor device of claim 3, wherein
a distance between the conductive film and the contact is laid out according to a minimum rule of each generation.

9. A semiconductor device, comprising:
an anti-fuse element comprising
a first wire formed on a substrate,
a second wire formed above the first wire with an insulator interposed between the first wire and the second wire, and
a via located in a layer between the first wire and the second wire, the via being connected directly to one of the first wire and the second wire and being spaced apart from the other one of the first wire and the second wire through the insulator, the via being short-circuited to the other one of the first wire and the second wire.

10. The semiconductor device of claim 9, wherein
the via has a tapered shape with a diameter increasing from a lower portion side toward an upper portion side of the via.

11. The semiconductor device of claim 9, wherein
the first wire, the second wire, and the via are each formed of copper.

12. The semiconductor device of claim 9, wherein
a barrier film is formed between the second wire and the via, between the second wire and the insulator, and between the first wire and the insulator.

13. The semiconductor device of claim 12, wherein
the barrier film is formed of any one of a titanium film, a titanium nitride film, and a tantalum film.

14. The semiconductor device of claim 1, wherein
a distance between the via and the other wire is laid out according to a minimum rule of each generation.

15. A method of fabricating a semiconductor device, comprising:
forming an insulator on a substrate;
forming a poly-crystalline silicon film on the insulator;
patterning the poly-crystalline silicon film to form a gate structure;
forming an silicon nitride film on the substrate;
etching the silicon nitride film isotropically to leave the silicon nitride film on a side-wall of the gate structure in order to form a side-wall film;
forming a metal film on the poly-crystalline silicon film of the gate structure;
performing heat treatment to form both a metal-silicide film including the metal film on the poly-crystalline silicon film and exposing at least an upper portion of a side-wall of the metal-silicide film;
forming an inter-layer insulator above the substrate to cover the upper portion of a side-wall of the metal-silicide film;
forming a contact hole in the inter-layer insulator;
embedding a conductive material in the contact hole to form a contact; and
short-cutting between the metal-silicide film and the contact via the inter-layer insulator.

16. The method of claim 15, wherein
a diameter of the contact hole is increased from a lower side towards an upper side in forming the contact hole.

17. The method of claim 15, wherein
the inter-layer insulator is composed of a silicon oxide film.

18. The method of claim 15, wherein
the metal-silicide film is composed of a nickel-silicide film or platinum-silicide film.
